(19) United States
(12) Patent Application Publication
(10) Pub. No.: US 2024/0404899 A1
(43) Pub. Date: Dec. 5, 2024

(54) ELECTRONIC DEVICE AND MANUFACTURING METHOD THEREOF

(71) Applicant: Innolux Corporation, Miaoli County (TW)

(72) Inventors: Ching-Wei Chen, Miaoli County (TW); Hsiu-Hsien Hsiao, Miaoli County (TW)

(73) Assignee: Innolux Corporation, Miaoli County (TW)

(21) Appl. No.: 18/654,000

(22) Filed: May 3, 2024

Related U.S. Application Data
(60) Provisional application No. 63/470,997, filed on Jun. 5, 2023.

(30) Foreign Application Priority Data
Mar. 8, 2024 (CN) 202410266833.6

(51) Int. Cl. H01L 23/31; H01L 21/56; H01L 21/768; H01L 23/498

(52) U.S. Cl. CPC H01L 23/3114; H01L 21/563; H01L 21/76843; H01L 21/76894; H01L 23/49816

(57) ABSTRACT

An electronic device is provided. The electronic device includes a chip, a protective layer, an encapsulation layer, and a circuit structure. The chip includes a base layer and at least one pad. The at least one pad is disposed on a first side of the base layer. The protective layer is disposed on the first side and has at least one opening. The at least one opening exposes a portion of the at least one pad. The encapsulation layer surrounds the chip and the protective layer. The circuit structure is disposed on the encapsulation layer and is electrically connected to the chip. The at least one pad has a concave surface. A portion of the circuit structure contacts the concave surface. A manufacturing method of the electronic device is also provided.

### CROSS-REFERENCE TO RELATED APPLICATION

This application claims the priority benefit of U.S. provisional application Ser. No. 63/470,997, filed on Jun. 5, 2023, and China application serial no. 202410266833.6, filed on Mar. 8, 2024. The entirety of each of the above-mentioned patent applications is hereby incorporated by reference herein and made a part of this specification.

### BACKGROUND

### Technical Field

The disclosure relates to an electronic device and a manufacturing method thereof, and in particular to an electronic device and a manufacturing method thereof that can reduce impedance.

### Description of Related Art

The electronic device or the splicing electronic device is widely applied in different fields such as communication, display, automotive, or aviation. With the rapid development of the electronic device, the electronic device is developing to become lighter and thinner, so the reliability or quality requirement for the electronic device is becoming higher.

### SUMMARY

The disclosure provides an electronic device and a manufacturing method thereof that can reduce damage to a pad (or a metal layer) or reduce impedance between the pad (or the metal layer) and other conductive materials.

According to an embodiment of the disclosure, an electronic device includes a chip, a protective layer, an encapsulation layer, and a circuit structure. The chip has a base layer and at least one pad. The at least one pad is disposed on a first side of the base layer. The protective layer is disposed on the first side and has at least one opening. The at least one opening exposes a portion of the at least one pad. The encapsulation layer surrounds the chip and the protective layer. The circuit structure is disposed on the encapsulation layer and is electrically connected to the chip. The at least one pad has a concave surface. A portion of the circuit structure contacts the concave surface.

According to an embodiment of the disclosure, and a manufacturing method of an electronic device includes the following steps. A chip is provided. The chip has a base layer and at least one pad, and the at least one pad is disposed on a first side of the base layer. A protective layer is formed on the first side. The protective layer has at least one opening, and the at least one opening exposes a portion of the at least one pad. An encapsulation layer is formed to surround the chip and the protective layer. A circuit structure is formed on the encapsulation layer to electrically connect the chip. The at least one pad has a concave surface, and a portion of the circuit structure contacts the concave surface

### BRIEF DESCRIPTION OF THE DRAWINGS

The drawings are included to provide a further understanding of the disclosure, and the drawings are incorporated into the specification and constitute a part of the specification. The drawings illustrate embodiments of the disclosure and serve to explain principles of the disclosure together with the description.

FIG. 1A to FIG. 1F are schematic cross-sectional views of a manufacturing method of an electronic device according to a first embodiment of the disclosure.

FIG. 2 is a schematic cross-sectional view of a manufacturing method of an electronic device according to a second embodiment of the disclosure.

FIG. 3 is a schematic cross-sectional view of a manufacturing method of an electronic device according to a third embodiment of the disclosure.

FIG. 4 is a schematic cross-sectional view of a manufacturing method of an electronic device according to a fourth embodiment of the disclosure.

FIG. 5 is a schematic cross-sectional view of an electronic device according to a fifth embodiment of the disclosure.

FIG. 6 is a schematic cross-sectional view of an electronic device according to a sixth embodiment of the disclosure.

FIG. 7 is a schematic cross-sectional view of an electronic device according to a seventh embodiment of the disclosure.

FIG. 8 is a schematic cross-sectional view of an electronic device according to an eighth embodiment of the disclosure.

### DESCRIPTION OF THE EMBODIMENTS

The disclosure may be understood with reference to the following detailed description taken in conjunction with the drawings. It should be noted that for the ease of understanding by the reader and the conciseness of the drawings, multiple drawings of the disclosure only depict a portion of an electronic device, and specific elements in the drawings may not be drawn according to actual scale. Furthermore, the number and the size of each element in the drawings are illustrative only and are not intended to limit the scope of the disclosure.

In the following specification and claims, terms such as “containing” and “including” are open-ended terms and should thus be interpreted to mean “comprising but not limited to . . . ”.

It should be understood that when an element or a film layer is referred to as being “on” or “connected to” another element or film layer, the element or film layer may be directly on the other element or film layer or directly connected to the other element or film layer, or there may be an element or a film layer inserted between the two (case of indirect connection). In contrast, when an element or a film layer is referred to as being “directly on” or “directly connected to” another element or film layer, there is no element or film layer inserted between the two.

Although terms such as “first”, “second”, and “third” may be used to describe multiple constituent elements, the constituent elements are not limited by the terms. The terms are only used to distinguish a single constituent element from other constituent elements in the specification. The claims may not use the same terms, which may be replaced by first, second, third . . . in the order of declaration of the elements in the claims. Therefore, in the following specification, a first constituent element may be a second constituent element in the claims.

In the text, the terms “about”, “approximately”, “substantially”, and “roughly” usually mean within 10%, 5%, 3%, 2%, 1%, or 0.5% of a given value or range. The number given here is an approximate number, that is, in the case where “about”, “approximately”, “substantially”, and “roughly” are not particularly described, the meanings of “about”, “approximately”, “substantially”, and “roughly” may still be implied.

In some embodiments of the disclosure, terms related to bonding and connection such as “connection” and “interconnection”, unless otherwise specified, may mean that two structures are in direct contact or may also mean that the two structures are not in direct contact, wherein there is another structure disposed between the two structures. Also, the terms related to bonding and connection may also include the case where the two structures are both movable or the two structures are both fixed. In addition, the term “coupling” includes any direct and indirect electrical connection means.

In some embodiments of the disclosure, an optical microscope (OM), a scanning electron microscope (SEM), a thin film thickness profilometer (a-step), an ellipsometer, or other suitable manners may be used to measure an area, a width, a thickness, or a height of each element or a distance or a spacing between elements. In detail, according to some embodiments, the scanning electron microscope may be used to obtain a cross-sectional structural image including the element to be measured and measure the area, the width, the thickness, or the height of each element or the distance or the spacing between the elements.

In some embodiments of the disclosure, “rough” means that by SEM observation, multiple surface protrusions and multiple surface recessions may be seen on a surface, and there is a height difference of at least 0.1 to 5 μm between a peak of each surface protrusion among the surface protrusions and a valley of each surface recession among the surface recessions. The determination of “roughness” herein may include using the SEM, a transmission electron microscope (TEM), etc. to observe surface undulations under the same appropriate magnification, and taking a unit length (for example, 10 μm) to compare the undulation conditions. Here, “appropriate magnification” means that the peaks of at least 5 surface protrusions and the valleys of at least 5 surface recessions may be observed for at least one surface under the field of view of the magnification. Let a value of a reference line L be 0, values toward the side of peak points Rp1 to Rp5 are positive and values toward the side of valley points Rv1 to Rv5 are negative. A difference value between the peak point Rp1 and the valley point Rv1, a difference value between the peak point Rp2 and the valley point Rv2, a difference value between the peak point Rp3 and the valley point Rv3, a difference value between the peak point Rp4 and the valley point Rv4, and a difference value between the peak point Rp5 and the valley point Rv5 are respectively calculated. A roughness Rz is an average value of the sum of the 5 difference values. Therefore, the roughness Rz may be expressed by the following equation, where an extension direction of the reference line L is a normal direction of a vertical electronic device:

$${R}_{Z} = \frac{1}{5} {\sum }_{i = 1}^{5} {R}_{pi} - {R}_{vi}$$

The electronic device of the disclosure may include a power management device, a display device, an antenna device, a communication device, a sensing device, or a splicing device, but not limited thereto. The electronic device may be a bendable or flexible electronic device. The electronic device may, for example, include liquid crystal (LC), a light emitting diode, quantum dot (QD), fluorescence, phosphor, other suitable materials, or any permutation and combination of the above materials, but not limited thereto. The light emitting diode may, for example, include an organic light emitting diode (OLED), a mini LED, a micro LED, or a quantum dot (QD) LED (which may, for example, be QLED or QDLED), but not limited thereto. The antenna device may, for example, be a phased array antenna, but not limited thereto. The splicing device may, for example, be a display splicing device or an antenna splicing device, but not limited thereto. It should be noted that the electronic device may be any permutation and combination of the above, but not limited thereto. The content of the disclosure will be described below with the electronic device, but the disclosure is not limited thereto.

It should be noted that in the following embodiments, without departing from the spirit of the disclosure, features in several different embodiments may be replaced, reorganized, and mixed to complete other embodiments. As long as the features of the embodiments do not violate the spirit of the invention or are not conflicting, the features may be arbitrarily mixed and matched for use.

Reference will now be made in detail to the exemplary embodiments of the disclosure, and examples of the exemplary embodiments are illustrated in the drawings. Wherever possible, the same reference numerals are used in the drawings and the description to refer to the same or similar parts.

A manufacturing method of the electronic device of the disclosure may be, for example, applied in a wafer-level package (WLP) or panel-level package (PLP) process and may be chip first or chip last redistribution layer (RDL) first manufacturing method. In the following, the chip first redistribution layer first manufacturing method is used as an example for illustration, but not limited thereto.

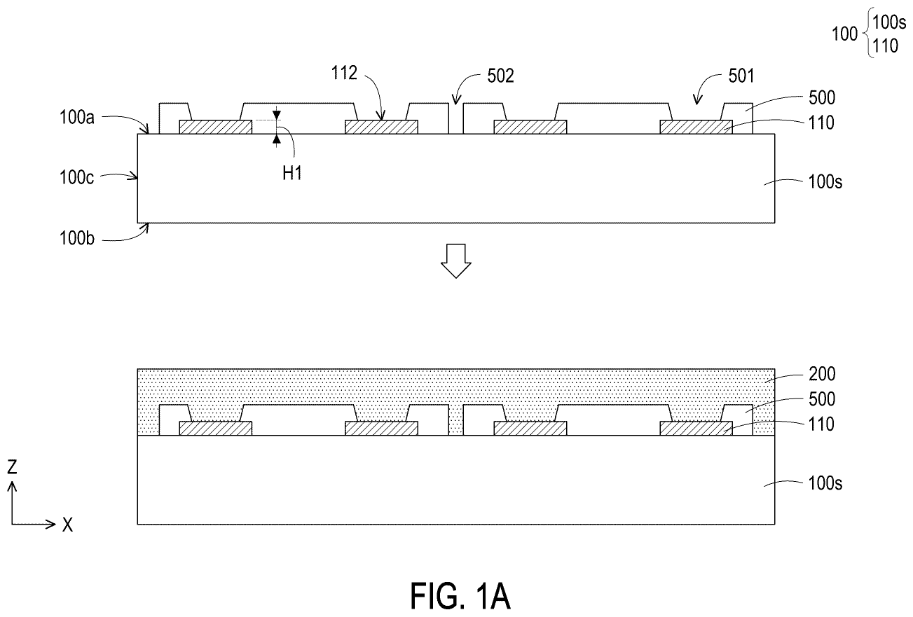

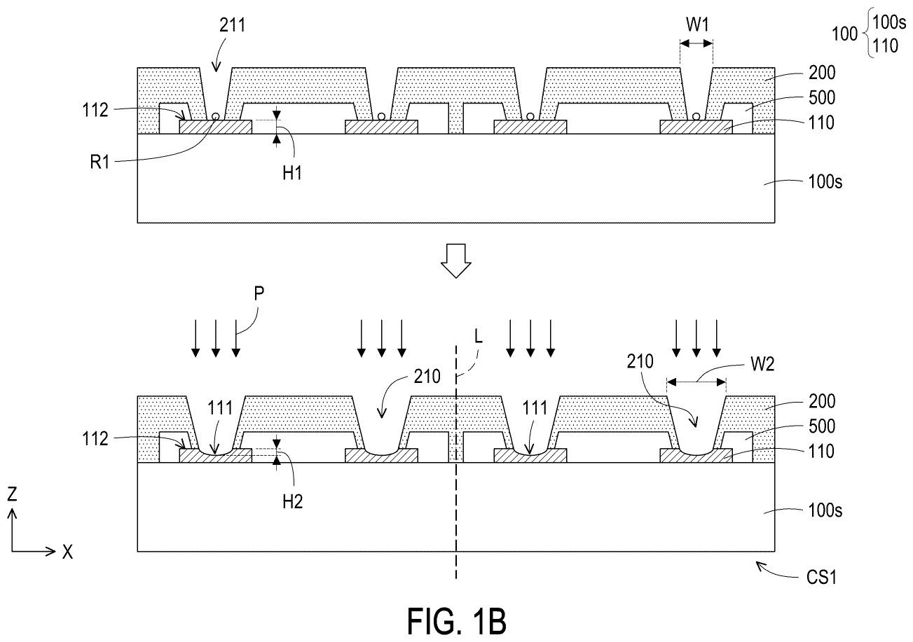

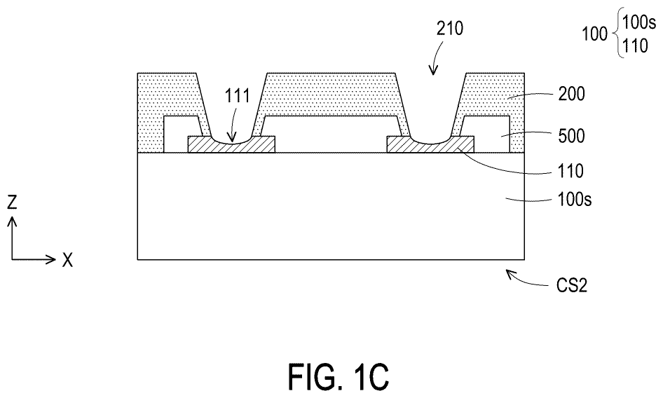

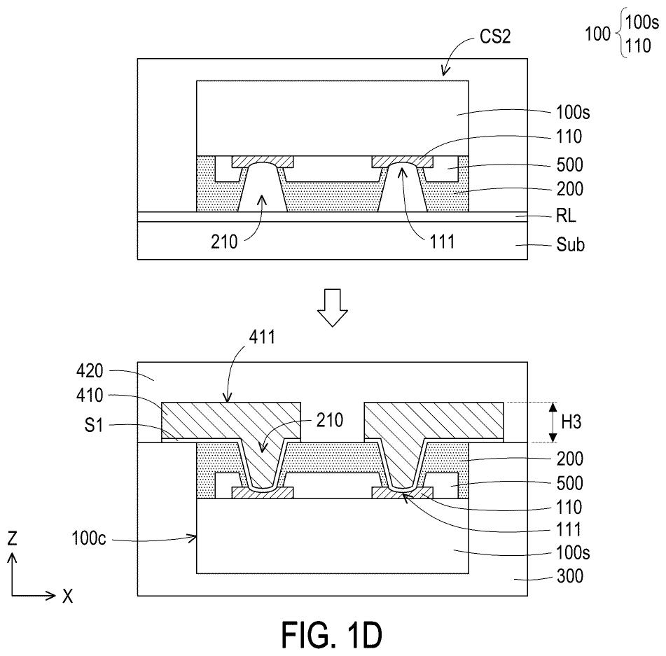

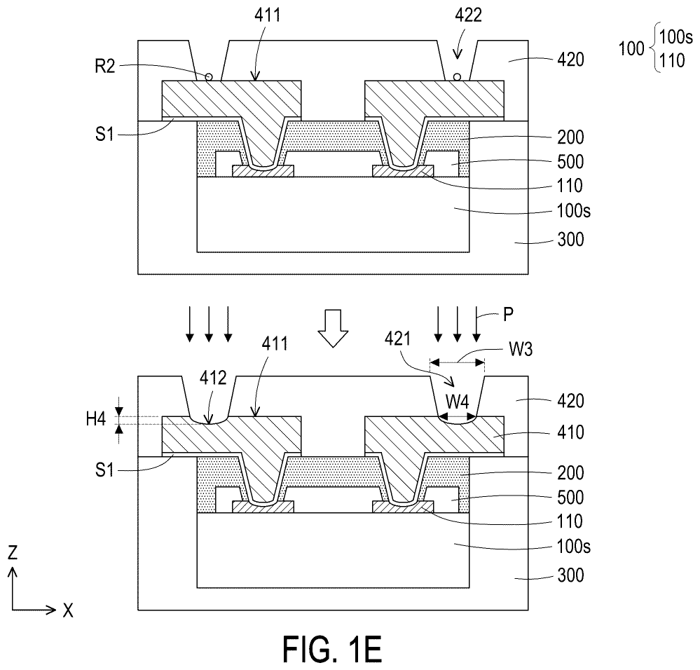

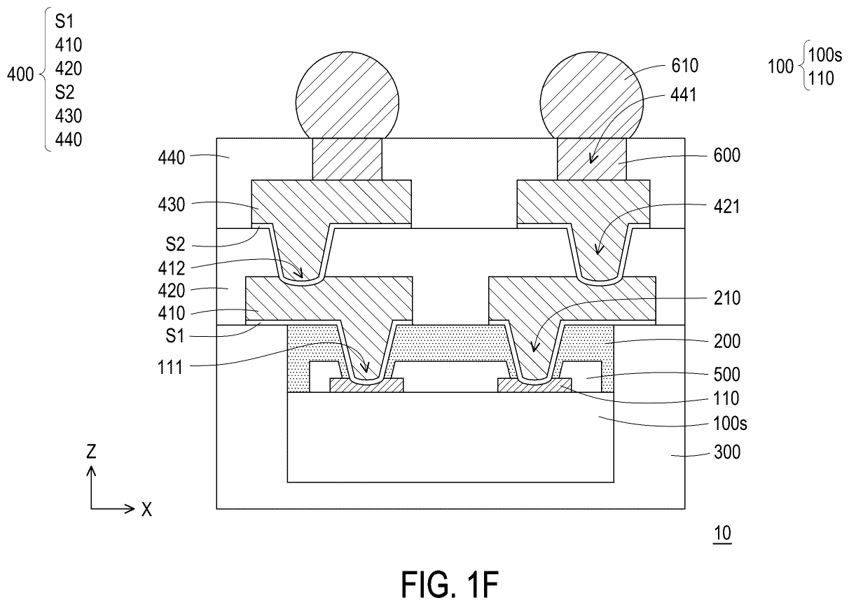

FIG. 1A to FIG. 1F are schematic cross-sectional views of a manufacturing method of an electronic device according to a first embodiment of the disclosure. Please refer to FIG. 1F first. An electronic device 10 of the embodiment may include a chip 100, a protective layer 200, an encapsulation layer 300, and a circuit structure 400. The chip 100 has base layer 100s and at least one pad 110. The at least one pad 110 is disposed on the base layer 100s. The chip 100 includes a first side. Furthermore, the base layer 100s is disposed on a first side 100a of the pad 110, which may be referred to as the first side of the chip 100. The protective layer 200 is disposed on the first side 100a of the base layer 100s and has at least one opening 210. The at least one opening 210 exposes a portion of the at least one pad 110. The encapsulation layer 300 surrounds the chip 100 and the protective layer 200. For example, in the cross-sectional view, the encapsulation layer 300 is arranged to directly contact at least two sides of the chip 100 to form a packaging structure. The encapsulation layer 300 may be a soft film, powder or a liquid encapsulation material before being provided. For example, it may include a pre-polymerized epoxy molding compound (EMC) encapsulation material, but the present disclosure is not limited thereto. The encapsulation layer 300 in direct contact with the corresponding component is, for example, advantageous to keep moisture or oxygen from contacting or from penetrating the corresponding component, that is, it may improve the weather resistance of the electronic device, but the present disclosure is not limited thereto. The circuit structure 400 is disposed on the encapsulation layer 300 and is electrically connected to the chip 100. The at least one pad 110 has a concave surface 111. A portion of the circuit structure 400 contacts the concave surface 111. For example, when the at least one pad 110 has a concave, the bonding ability of the at least one pad 110 with other components can be improved, but not limited thereto. The electronic device 10 of the embodiment may be applied to a power module, a semiconductor packaging device, a display device, a light emitting device, a backlight device, an antenna device, a sensing device, or a splicing device, but not limited thereto.

Then, a manufacturing method of the electronic device 10 of the embodiment will be described below. In the embodiment, the manufacturing method of the electronic device 10 may include, but is not limited to, the following steps and the sequence thereof.

First, please refer to FIG. 1A. The chip 100 is provided on a carrier plate (not shown) having a release layer, an insulation layer 500 is formed on the chip 100, and the protective layer 200 is formed on the chip 100 and the insulation layer 500. Specifically, the base layer 100s of the chip 100 has the first side 100a, a second side 100b, and a lateral surface 100c, wherein the first side 100a and the second side 100b are opposite to each other, and the lateral surface 100c connects the first side 100a and the second side 100b. The chip 100 includes the at least one pad 110 (FIG. 1A schematically shows 4 pads 110, but not limited thereto), and the pad 110 is disposed on the first side 100a of the base layer 100s. The pad 110 has a surface 112 away from the base layer 100s. The pad 110 has a height H1, and the height H1 is, for example, the maximum height of the pad 110 measured along a direction Z (that is, a normal direction of the chip 100 or a normal direction of the base layer 100s). In the embodiment, the base layer 100s may include an organic material, glass, a wafer, a silicon substrate, a doped silicon substrate, gallium nitride, other suitable substrate semiconductor materials, or a combination thereof, but not limited thereto. In the embodiment, the material of the pad 110 may include aluminum, titanium, copper, molybdenum, silver, gold, tantalum, other suitable conductive materials, or a combination thereof, but not limited thereto.

The insulation layer 500 is disposed on the first side 100a of the base layer 100s, and the insulation layer 500 is disposed between the chip 100 and the protective layer 200. The insulation layer 500 has an opening 501 and an opening 502. The opening 501 exposes a portion of the pad 110, and the opening 502 exposes a portion of the chip 100. In the embodiment, the material of the insulation layer 500 may include silicon oxide, silicon nitride, aluminum oxide, polyimide (PI), photosensitive polyimide (PSPI), other suitable inorganic materials, other suitable organic materials, or a combination thereof, but not limited thereto. In some embodiments, along the direction Z, the insulation layer 500 may be a single layer or a multi-layer stack, and the thickness of the insulation layer 500 may be between 0.5 μm and 10 μm. In some embodiments, the insulation layer 500 may have a coefficient of thermal expansion (CTE) of 0.01 ppm/° C. to 5 ppm/° C. and a Young's modulus of 100 GPa to 300 GPa, but not limited thereto.

The protective layer 200 is disposed on the insulation layer 500, in the opening 501, and in the opening 502, and the protective layer 200 may cover a portion of the pad 110 and a portion of the chip 100 exposed by the insulation layer 500, for example, to improve adhesion between the protective layer 200 and the insulation layer 500, but not limited thereto. The protective layer 200 can reduce the possibility of cracking of the chip 100 during a subsequent singulation process. In the embodiment, the material of the protective layer 200 may include an organic material. For example, the material of the protective layer 200 may be polyimide, photosensitive polyimide, epoxy resin, Ajinomoto build-up film (ABF), other suitable polymer materials, or a combination thereof, but not limited thereto. In some embodiments, along the direction Z, the thickness of the protective layer 200 is between 5 μm and 30 μm, and the material of the protective layer 200 may also include a filling material with a particle size of 0.05 μm to 20 μm, but not limited thereto. In some embodiments, the protective layer 200 may have a coefficient of thermal expansion (CTE) of 10 ppm/° C. to 40 ppm/° C., a Young's modulus of 3 GPa to 15 GPa, and a tensile strength of 50 MPa to 110 MPa, but not limited thereto. Through the above design, the possibility of cracking of the chip 100 during the singulation process can be reduced, but not limited thereto.

Next, please refer to FIG. 1B. The at least one opening 210 (FIG. 1B schematically shows 4 openings 210, but not limited thereto) of the protective layer 200 is formed using a first surface treatment process to expose a portion of the pad 110 and form the concave surface 111 of the pad 110, so as to manufacture a chip structure CS1.

Specifically, the first surface treatment process may include a laser drilling process, a plasma etching process P, a chemical etching process, or a combination thereof, but not limited thereto. A forming step of the at least one opening 210 and the concave surface 111 may include the following step. First, the laser drilling process is performed on the protective layer 200 to form a first opening 211 of the surface 112 that may expose a portion of the pad 110. Next, the plasma etching process P is performed on the first opening 211 to remove a residue R1 in the first opening 211 (for example, a metal oxide on the pad 110 and/or a residual part of the protective layer 200 remaining in the first opening 211 after the drilling process), and form the opening 210 and the concave surface 111 of the pad 110. Therefore, compared with the general manner of performing the first surface treatment process only using the laser drilling process, the first surface treatment process of the embodiment uses the laser drilling process combined with the plasma etching process P, which can reduce damage to the pad 110 or reduce the residue R1 in the opening 210, thereby reducing impedance (or contact resistance) between the pad 110 and other conductive materials, improving the electrical properties of the pad 110, or improving the adherence ability between the pad 110 and other conductive materials. According to some embodiments, the first surface treatment process may include the use of a gas, such as oxygen, carbon monoxide, carbon dioxide, a fluorine-containing gas, a sulfur-containing gas, an inert gas, a reducing gas, or a combination thereof, but not limited thereto. According to some embodiments, the first surface treatment process may further include performing a cleaning step on the first opening 211 after the plasma etching process P. The cleaning step includes using a solvent or a gas, but not limited thereto. Through the first surface treatment process, the electrical properties of the pad 110 can be improved or the adherence ability between the pad 110 and other conductive materials can be improved, but not limited thereto.

The first opening 211 and the opening 210 of the protective layer 200 respectively have a width W1 and a width W2. The width W1 is, for example, the maximum width of the top of the first opening 211 measured along a direction X (that is, a horizontal direction in the drawing), and the width W2 is, for example, the maximum width of the top of the opening 210 measured along the direction X. In the embodiment, the width W2 of the opening 210 may be greater than the width W1 of the first opening 211, but not limited thereto.

In the embodiment, the plasma etching process P may include at least one plasma etching step. For example, the plasma etching process P may, for example, be performing the plasma etching step once using a plasma etching method with a high etching rate; or the plasma etching process P may also, for example, be first performing the plasma etching step for the first time using the plasma etching method with the high etching rate, and then performing the plasma etching step for the second time using a plasma etching method with a low etching rate (that is, performing two plasma etching steps). In the embodiment, the plasma etching method with the high etching rate may include inductively coupled plasma-capacitive coupled plasma (ICP-CCP) or inductively coupled plasma-reactive ion etching (ICP-RIE), and the plasma etching method with the low etching rate may include high density plasma (HDP), but not limited thereto. In addition, in the embodiment, the plasma etching process P may, for example, adopt a fluorine-based gas, but not limited thereto.

The concave surface 111 of the pad 110 is, for example, a surface of the pad 110 that is concave in a direction from the surface 112 toward the chip 100. The concave surface 111 may be connected to the surface 112, the concave surface 111 and the surface 112 are non-coplanar, and the concave surface 111 may overlap with the opening 210 in the direction Z and the portion of the circuit structure 400 contacts the concave surface through the least one opening 210 of the protective layer 200. The concave surface 111 has a depth H2, wherein the depth H2 is, for example, the minimum distance measured between the surface 112 of the pad 110 and the bottom of the concave surface 111 along the direction Z. In the embodiment, the depth H2 of the concave surface 111 of the at least one pad 110 may be 30 nm to 70 nm to ensure that the depth H2 of the concave surface 111 is not too deep to affect the conductivity of the pad 110, but not limited thereto. In the embodiment, a ratio of the depth H2 of the concave surface 111 of the at least one pad 110 to the height H1 of the at least one pad 110 may be 1% to 15% (that is, 1%≤H2/H1≤15%) or 3% to 10% (that is, 3%≤H2/H1≤10%) to ensure that the depth H2 of the concave surface 111 is not too deep to affect the conductivity of the pad 110, but not limited thereto.

Next, please refer to FIG. 1B and FIG. 1C at the same time. The singulation process is performed. Specifically, a cutting tool is used to cut the large chip structure CS1 shown in FIG. 1B into a small chip structure CS2 shown in FIG. 1C along a cutting line L in FIG. 1B.

Next, please refer to FIG. 1D to FIG. 1F. First, a carrier plate sub and a release layer RL disposed on the carrier plate sub are provided. Then, the chip structure CS2 as shown in FIG. 1C is flipped upside down, and the flipped chip structure CS2 is fixed on the release layer RL. Then, the encapsulation layer 300 is formed on the carrier plate sub and the release layer RL, so that the encapsulation layer 300 may surround the chip 100 and the protective layer 200. Then, the release layer RL and the carrier plate sub are removed, and the chip structure CS2 is flipped upside down again. Then, the circuit structure 400 is formed on the encapsulation layer 300, so that the circuit structure 400 may be electrically connected to the chip 100. Then, a conductive stud 600 is formed on the circuit structure 400, and a connection pad 610 is formed on the conductive stud 600.

In detail, please continue to refer to FIG. 1D. After forming the encapsulation layer 300 and removing the release layer RL and the carrier plate sub, a first seed layer S1 is formed on the encapsulation layer 300, a first metal layer 410 is formed on the first seed layer S1, and a first insulation layer 420 is formed on the first metal layer 410. The thickness of the first seed layer S1 may be between 0.1 μm and 1 μm. Through providing the seed layer on the insulation layer, the bonding force between a subsequent film layer and the insulation layer can be improved, but not limited thereto. The thickness of the first metal layer 410 may be between 5 μm and 25 μm. Specifically, in the cross-sectional view, the encapsulation layer 300 may at least contact the lateral surface 100c of the chip 100. The first seed layer S1 may be disposed on the protective layer 200, on the encapsulation layer 300, and in the opening 210. The first metal layer 410 may be disposed on the first seed layer S1 and in the opening 210. The first metal layer 410 has a surface 411 away from the chip 100 along the direction Z. The first metal layer 410 may be electrically connected to the pad 110 of the chip 100 through the first seed layer S1. The first metal layer 410 has a height H3, and the height H3 is, for example, a height of the first metal layer 410 measured along the direction Z. In the embodiment, the height H3 of the first metal layer 410 may be 5 μm to 25 μm (that is, 5 μm≤H3≤25 μm) or 10 μm to 20 μm (that is, 10 μm≤H3≤20 μm), but not limited thereto. A roughness (Rz) of the surface 411 of the first metal layer 410 may be 0.1 μm to 5 μm, but not limited thereto. The first insulation layer 420 may cover a portion of the protective layer 200 and a portion of the encapsulation layer 300. Specifically, the first insulation layer 420 may directly contact a portion of the protective layer 200 and a portion of the encapsulation layer 300.

Please continue to refer to FIG. 1E. A via 421 of the first insulation layer 420 (FIG. 1E schematically shows 2 vias 421, but not limited thereto) is formed using a second surface treatment process to expose a portion of the first metal layer 410 and form a recession 412 of the first metal layer 410. Specifically, the second surface treatment process may include a laser drilling process, a plasma etching process P, and a micro etching process, but not limited thereto. The forming step of the via 421 and the recession 412 may include the following steps. First, the laser drilling process is performed on the first insulation layer 420 to form a first via 422 that may expose a portion of the surface 411 of the first metal layer 410. Next, the plasma etching process P is performed on the first via 422 to remove a residue R2 in the first via 422 (for example, a metal oxide on the first metal layer 410 and/or a residual part of the first insulation layer remaining in the first via 422 after the drilling process), and form the via 421 and the recession 412 of the first metal layer 410. Next, the micro etching process (for example, wet etching) is performed on the via 421 to improve the adherence ability of the recession 412 through adjusting the roughness of the surface of the recession 412. Therefore, compared with the general manner of performing the second surface treatment process only using the laser drilling process, the second surface treatment process of the embodiment uses the laser drilling process combined with the plasma etching process P, which can reduce damage to the first metal layer 410 or reduce the residue R2 in the via 421, thereby reducing impedance (or contact resistance) between the first metal layer 410 and other conductive materials, improving the electrical properties of the first metal layer 410, or improving the adherence ability between the first metal layer 410 and other conductive materials.

The via 421 of the first insulation layer 420 has a top width W3 and a bottom width W4. The top width W3 is, for example, the maximum width of the top of the via 421 measured along the direction X, and the bottom width W4 is, for example, the maximum width of the bottom of the via 421 measured along the direction X. In the embodiment, a ratio of the bottom width W4 to the top width W3 may be 0.3 to 0.5 (that is, 0.3≤W4/W3≤0.5), but not limited thereto.

The recession 412 of the first metal layer 410 is, for example, a groove of the first metal layer 410 that is concave in a direction from the surface 411 toward the chip 100. The recession 412 may be connected to the surface 411, the recession 412 and the surface 411 are non-coplanar, and the recession 412 may overlap with the via 421 in the direction Z. The recession 412 has a depth H4, wherein the depth H4 is, for example, the minimum distance between the surface 411 of the first metal layer 410 and the bottom of the recession 412 measured along the direction Z. In the embodiment, the depth H4 of the recession 412 of the first metal layer 410 may be 0.1 μm to 5 μm (that is, 0.1 μm≤H4≤5 μm) or 0.5 μm to 3 μm (that is, 0.5 μm≤H4≤3 μm) to ensure that the depth H4 of the recession 412 is not too deep to affect the conductivity of the first metal layer 410, but not limited thereto.

Please continue to refer to FIG. 1F. After forming the via 421 of the first insulation layer 420 and the recession 412 of the first metal layer 410, a second seed layer S2 is formed on the first insulation layer 420, a second metal layer 430 is formed on the second seed layer S2, and a second insulation layer 440 is formed on the second metal layer 430. Specifically, the second seed layer S2 may be disposed on the first insulation layer 420 and in the via 421. The second metal layer 430 may be disposed on the second seed layer S2 and in the via 421. The second metal layer 430 may be electrically connected to the first metal layer 410 through the second seed layer S2. The second insulation layer 440 may cover a portion of the first insulation layer 420. The second insulation layer 440 has an opening 441 (FIG. 1F schematically shows 2 openings 441, but not limited thereto), and the opening 441 may expose a portion of the second metal layer 430.

In the embodiment, the circuit structure 400 may be a redistribution layer (RDL) or a RDL structure, and the circuit structure 400 may be electrically connected to other chips or electronic units through a solder ball, a connection pad, or other bonding elements. In the embodiment, the circuit structure 400 may include a stack structure of at least one metal layer (that is, the first metal layer 410 and the second metal layer 430) and at least one insulation layer (that is, the first insulation layer 420 and the second insulation layer 440), the circuit structure 400 may redistribute circuits and/or further increase a circuit fan-out area, or the circuit structure 400 may enable different electronic elements to be electrically connected to each other through the redistribution layer or the redistribution structure of the circuit structure 400. For example, the circuit structure 400 may adjust a spacing between contact pads, thereby adjusting the circuit fan-out area. For example, a spacing between two adjacent contact pads of a circuit structure contacting an end of a chip is less than a spacing between two adjacent contact pads of a circuit structure away from an end of the chip, but not limited thereto.

For example, as shown in FIG. 1F, the circuit structure 400 may include the first seed layer S1, the first metal layer 410, the first insulation layer 420, the second seed layer S2, the second metal layer 430, and the second insulation layer 440. The first seed layer S1 is disposed on the pad 110. The first metal layer 410 is disposed on the first seed layer S1, the first metal layer 410 may contact the concave surface 111 of the pad 110, and the first metal layer 410 has the recession 412. The first insulation layer 420 is disposed on the first metal layer 410 and includes the via 421. The second seed layer S2 is disposed on the first metal layer 410. The second metal layer 430 is disposed on the second seed layer S2 and the first insulation layer 420, the second metal layer 430 may contact the recession 412 of the first metal layer 410, and the second metal layer 430 may be electrically connected to the first metal layer 410 through the via 421 of the first insulation layer 420. The second insulation layer 440 is disposed on the second metal layer 430.

Although the circuit structure 400 of FIG. 1F exemplarily includes two seed layers (that is, the first seed layer S1 and the second seed layer S2), two metal layers (that is, the first metal layer 410 and the second metal layer 430), two insulation layers (that is, the first insulation layer 420 and the second insulation layer 440), two vias 421, two openings 441, and two recessions 412, the disclosure does not limit the number of seed layers, metal layers, insulation layers, vias, openings, and recessions in the circuit structure. It should be understood that the residue R2 in each via (for example, the metal oxide and/or the residual part of the insulation layer remaining in the via after the drilling process) should be reduced or each via may overlap with the recession of the metal layer in the direction Z.

In the embodiment, the silicon content of an interface between the first seed layer S1 and the pad 110 is less than 1% to reduce impedance (or contact resistance) between the first metal layer 410 and the pad 110, and the silicon content and/or the carbon content of an interface between the second seed layer S2 and the first metal layer 410 is less than 1% to reduce impedance (or contact resistance) between the second metal layer 430 and the first metal layer 410. For example, elemental analysis may be performed through the scanning electron microscope under an appropriate magnification, such as the magnification with a unit length of 20 μm. For example, a region with a suitable size may be selected from the interface between the second seed layer S2 and the first metal layer 410 for the elemental analysis. The area of the region may be 1 μm*1 μm, 3 μm*3 μm, or 5 μm*5 μm. The region must cover film layers to be analyzed and an interface between the two film layers at the same time.

In the embodiment, the first seed layer S1 and the second seed layer S2 may be single-layer or multi-layer metal layers, and the materials of the first seed layer S1 and the second seed layer S2 may include tantalum, titanium, copper, aluminum, nickel, indium-tin oxide (ITO), other suitable conductive materials, or a combination thereof, but not limited thereto. The first metal layer 410 and the second metal layer 430 may have single-layer structures or multi-layer structures, and the materials of the first metal layer 410 and the second metal layer 430 may include copper, titanium, chromium, aluminum, gold, nickel, tin, silver, an alloy of the above metals, other suitable conductive materials, or a combination thereof, but not limited thereto. The first insulation layer 420 and the second insulation layer 440 may have single-layer structures or multi-layer structures, and the materials of the first insulation layer 420 and the second insulation layer 440 may include photosensitive polyimide, Ajinomoto build-up film, other suitable insulation materials, or a combination thereof, but not limited thereto.

In the embodiment, a manufacturing method of the circuit structure 400 may include providing a stack structure of at least one metal layer and at least one insulation layer, and may include a processing step such as photolithography, etching, surface treatment, laser, and electroplating. The surface treatment includes roughening the surface of an insulation layer or the surface of a metal layer, so that the insulation layer or the metal layer may have a rough surface to improve the adherence ability thereof. In the embodiment, the rough surface may be determined by, for example, using tools such as the scanning electron microscope (SEM) or the transmission electron microscope (TEM), and taking a unit length (for example, 10 μm) to observe and compare the undulation conditions of the peaks and the valleys of the surface under an appropriate magnification. When there is a distance difference of 0.15 μm to 1 μm between the undulations of the peaks and the valleys of the surface, the surface is determined to be rough.

Please continue to refer to FIG. 1F. After forming the opening 441 of the second insulation layer 440, the conductive stud 600 is formed in the opening 441 of the second insulation layer 440, and the connection pad 610 is formed on the conductive stud 600. The conductive stud 600 may be electrically connected to the circuit structure 400 and the connection pad 610, and the chip 100 may be electrically connected to the connection pad 610 through the pad 110, the circuit structure 400, and the conductive stud 600. At this point, the manufacturing of the electronic device 10 of the embodiment may be roughly completed.

Other embodiments will be listed below as illustrations. It must be noted here that the following embodiments continue to use the reference numerals and some content of the foregoing embodiments, wherein the same numerals are adopted to represent the same or similar elements, and the description of the same technical content is omitted. For the description of the omitted part, reference may be made to the foregoing embodiments and will not be repeated in the following embodiments.

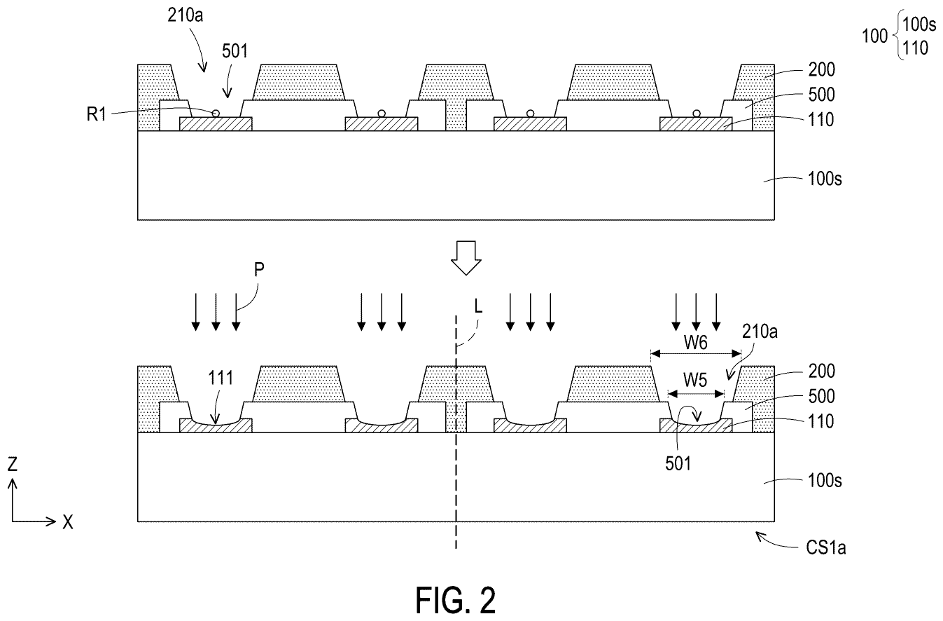

FIG. 2 is a schematic cross-sectional view of a manufacturing method of an electronic device according to a second embodiment of the disclosure. FIG. 2 is a continuation of FIG. 1A and replaces the steps of FIG. 1B. The same or similar components in the embodiment of FIG. 2 and the embodiment of FIG. 1A to FIG. 1F may adopt the same materials or methods. Therefore, the same and similar descriptions in the two embodiments will not be repeated below, and the difference between the two embodiments will be mainly illustrated.

Specifically, please refer to FIG. 2. When performing the first surface treatment process, the laser drilling process is first performed on the protective layer 200 to form an opening 210a that may expose the insulation layer 500, the opening 501, and the pad 110.

Next, the plasma etching process P is performed on the opening 501 to remove the residue R1 in the opening 501 (for example, the metal oxide on the pad 110 and/or the residual part of the protective layer 200 remaining in the opening 501 after the drilling process), and form the concave surface 111 of the pad 110 to manufacture a chip structure CS1a.

After the plasma etching process P is performed, the opening 501 of the insulation layer 500 and the opening 210a of the protective layer 200 respectively have a width W5 and width a W6. The width W5 is, for example, the maximum width of the top of the opening 501 measured along the direction X (that is, the horizontal direction of the drawing), and the width W6 is, for example, the maximum width of the top of the opening 210a measured along the direction X. In the embodiment, the width W6 of the opening 210a may be greater than the width W5 of the opening 501, but not limited thereto. So as said, the electronic device 10 includes that the opening 501 of the insulation layer 500 and the opening 210a of the protective layer 200 respectively have a width W5 and a width W6.

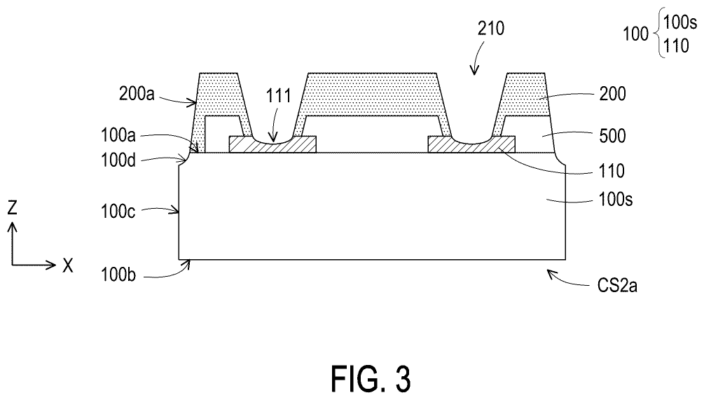

FIG. 3 is a schematic cross-sectional view of a manufacturing method of an electronic device according to a third embodiment of the disclosure. FIG. 3 is a continuation of FIG. 1B and replaces the steps of FIG. 1C. The same or similar components in the embodiment of FIG. 3 and the embodiment of FIG. 1A to FIG. 1F may adopt the same materials or methods. Therefore, the same and similar descriptions in the two embodiments will not be repeated below, and the difference between the two embodiments will be mainly illustrated.

Specifically, please refer to FIG. 3. In a small chip structure CS2a after cutting, a lateral surface 200a of the protective layer 200 is an inclined surface, and there is an arc surface 100d connecting the first side 100a and the lateral surface 100c of the base layer 100s of the chip 100. The protective layer 200 may expose the arc surface 100d of the chip 100. When the chip 100 has the arc surface 100d, the contact area can be increased, thereby improving the bonding ability with the encapsulation layer 300, but not limited thereto.

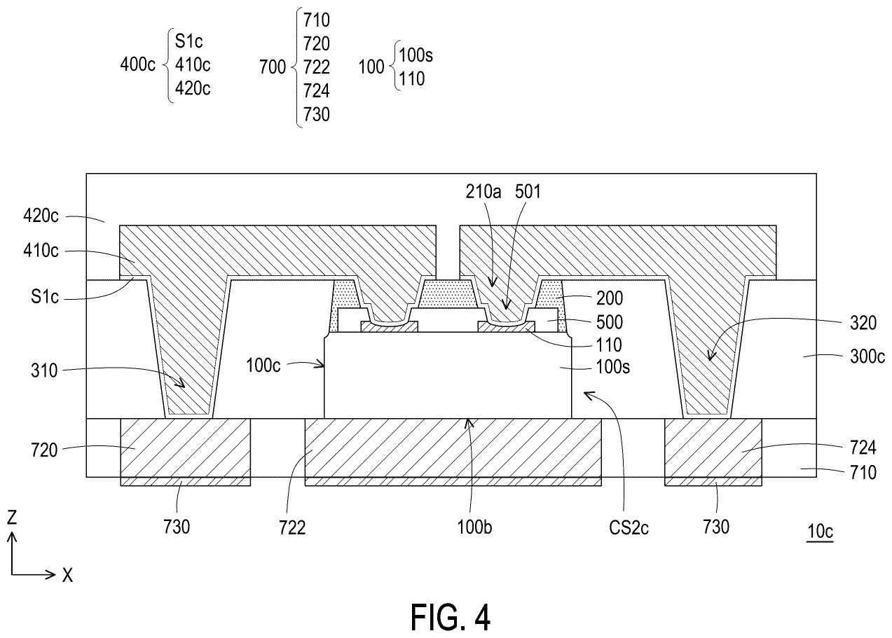

FIG. 4 is a schematic cross-sectional view of a manufacturing method of an electronic device according to a fourth embodiment of the disclosure. FIG. 4 is a continuation of FIG. 1A and replaces the steps of FIG. 1B to FIG. 1D or FIG. 4 is a continuation of FIG. 2 and replaces the steps of FIG. 1C and FIG. 1D. The same or similar components in the embodiment of FIG. 4 and the embodiment of FIG. 1A to FIG. 1F and FIG. 2 may adopt the same materials or methods. Therefore, the same and similar descriptions in the two embodiments will not be repeated below, and the difference between the two embodiments will be mainly illustrated.

Specifically, the singulation process is first performed to cut the large chip structure CS1a shown in FIG. 2 into a small chip structure CS2c using a cutting tool along the cutting line L in FIG. 2. Next, steps similar to FIG. 1D are performed. A carrier plate (not shown) and a release layer (not shown) disposed on the carrier plate are provided. The chip structure CS2c after being flipped upside down is fixed on the release layer. An encapsulation layer 300c is formed on the carrier plate and the release layer, so that the encapsulation layer 300c may surround the chip 100 and the protective layer 200. The release layer and the carrier plate are removed, and the chip structure CS2c surrounded by the encapsulation layer 300c is fixed on an interposer 700. A circuit structure 400c is formed on the encapsulation layer 300, so that the circuit structure 400c may be electrically connected to the chip 100 to manufacture an electronic device 10c as shown in FIG. 4.

Please refer to FIG. 4. In the electronic device 10c of the embodiment, the interposer 700 may include an insulation layer 710, multiple conductive studs (that is, a conductive stud 720, a conductive stud 722, and a conductive stud 724) and multiple connection pads 730. The conductive stud 720, the conductive stud 722, and the conductive stud 724 penetrate the insulation layer 710, and the connection pads 730 are respectively disposed on the conductive stud 720, the conductive stud 722, and the conductive stud 724.

The encapsulation layer 300c is disposed on the interposer 700. The encapsulation layer 300c may cover the lateral surface 100c of the chip 100 and expose the second side 100b of the chip 100. The encapsulation layer 300c may include a via 310 and a via 320 penetrating the encapsulation layer 300c. The via 310 may expose the conductive stud 720, and the via 320 may expose the conductive stud 724.

The circuit structure 400c may include a first seed layer S1c, a first metal layer 410c, and a first insulation layer 420c. The first seed layer S1c is disposed on the encapsulation layer 300c, in the via 310 and the via 320, on the protective layer 200, in the opening 210a, and in the opening 501. The first metal layer 410 may be disposed on the first seed layer S1, in the via 310 and the via 320, in the opening 210a, and in the opening 501. The first insulation layer 420 is disposed on the first metal layer 410, and the first insulation layer 420 may cover a portion of the protective layer 200 and a portion of the encapsulation layer 300c.

The first metal layer 410c may be electrically connected to the pad 110 of the chip 100 through the opening 210a and the opening 501. The first metal layer 410c may also be electrically connected to the conductive stud 720 (or the conductive stud 724) through the via 310 (or the via 320). In other words, the chip 100 may be electrically connected to the connection pad 730 through the pad 110, the opening 501, the opening 210a, the first metal layer 410c, and the conductive stud 720 (or the conductive stud 724). In addition, the chip 100 may also be electrically connected to the connection pad 730 through the conductive stud 722. Alternatively, according to some embodiments, a surface of the conductive stud 722 away from the chip 100 may not have the connection pad 730. Along a direction (that is, the direction X) perpendicular to the direction Z, the width of the conductive stud 722 is greater than or equal to the width of the chip 100. The width referred to is, for example, the maximum width. Through the above design, the conductive stud 722 can increase the heat dissipation capacity of the electronic device, but not limited thereto.

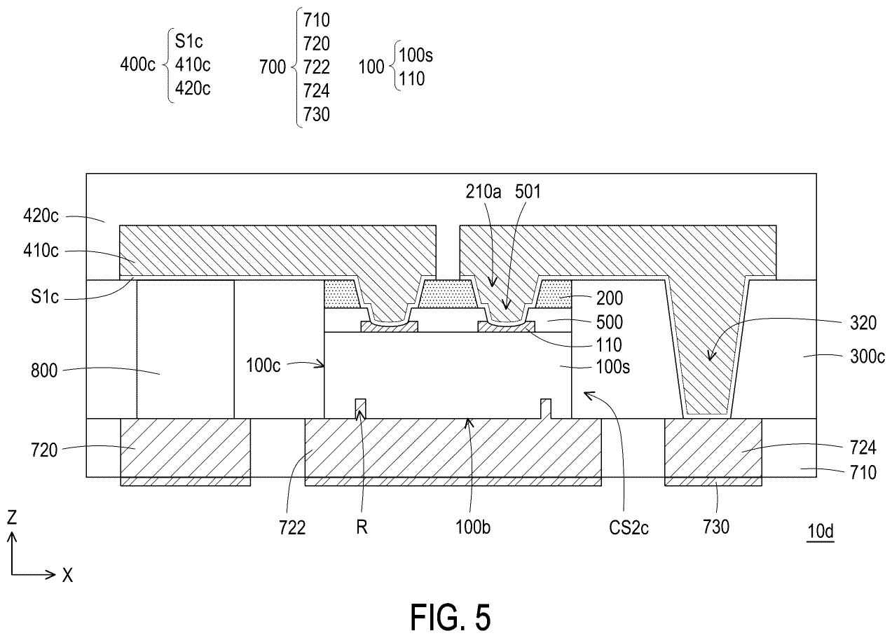

FIG. 5 is a schematic cross-sectional view of an electronic device according to a fifth embodiment of the disclosure. Please refer to FIG. 5 and FIG. 4 at the same time. An electronic device 10d of the embodiment is similar to the electronic device 10c in FIG. 4. The only difference between the two is that the electronic device 10d of the embodiment also includes an electronic element 800. Specifically, the electronic element 800 replaces the via 310 in the encapsulation layer 300c of FIG. 4. The electronic element 800 is disposed in the encapsulation layer 300c, and the electronic element 800 may be electrically connected to the corresponding first metal layer 410 and conductive stud 720. In some embodiments, the electronic element 800 may also be replaced by the electronic device 10 of FIG. 1F. The electronic element 800 may include silicon, doped silicon, a conductor, a capacitor, an inductor, or other suitable elements. In addition, in the electronic device 10d of the embodiment, the second side 100b of the base layer 100s of the chip 100 may have an accommodating space R, so that a portion of the conductive stud 722 may extend into the accommodating space R. Through such a design, the bonding ability or the heat dissipation effect can be improved, but not limited thereto.

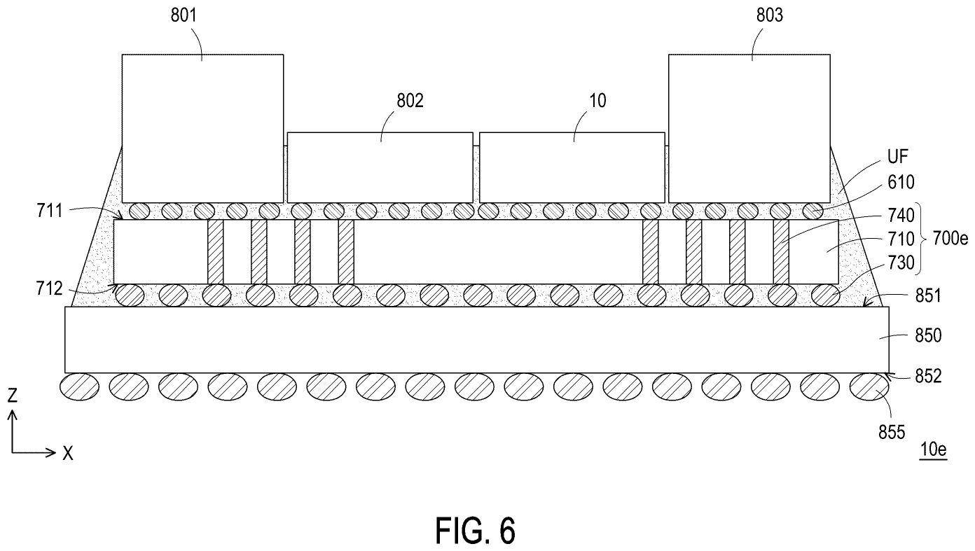

FIG. 6 is a schematic cross-sectional view of an electronic device according to a sixth embodiment of the disclosure. Please refer to FIG. 6 and FIG. 1F at the same time. An electronic device 10e of the embodiment is similar to the electronic device 10 in FIG. 1F. The only difference between the two is that the electronic device 10e of the embodiment also includes an electronic element 801, an electronic element 802, an electronic element 803, an interposer 700e, and a circuit board 850. Through the stack of elements, a structure in which a chip is disposed on an interposer and the interposer is disposed on a circuit board, such as chip on interposer on substrate (CoIoS), may be implemented, wherein the interposer may include glass, a silicon wafer, a redistribution structure, PSPI, an ABF carrier plate, a combination thereof, or other suitable insulation layers or dielectric layers. In addition, the electronic device 10e may further include an underfill UF. The underfill UF may be filled between the electronic element 801 and the interposer 700e or the underfill UF may be filled between the interposer 700e and the circuit board 850, and the underfill UF may contact the lateral surface of the electronic element.

Specifically, please refer to FIG. 6. The circuit board 850 has a surface 851 and a surface 852 opposite to each other. The circuit board 850 may include a connection pad 855, and the connection pad 855 is disposed on the surface 852 of the circuit board 850.

The interposer 700e is disposed on the surface 851 of the circuit board 850. The interposer 700e may include the insulation layer 710, the connection pads 730, and multiple vias 740. The insulation layer 710 has a surface 711 and a surface 712 opposite to each other. The connection pads 730 are respectively disposed on the surface 712 of the insulation layer 710, so that the interposer 700e may be bonded onto the surface 851 of the circuit board 850 through the connection pads 730. The vias 740 respectively penetrate the insulation layer 710, and the vias 740 may extend from the surface 711 to the surface 712 of the insulation layer 710. The vias 740 are filled with a conductive material, and the vias 740 may be respectively electrically connected to the corresponding connection pad 610 and the corresponding connection pad 730.

The electronic element 801, the electronic element 802, the electronic element 803, and the electronic device 10 of FIG. 1F include the connection pad 610, and the electronic element 801, the electronic element 802, the electronic element 803, and the electronic device 10 of FIG. 1F may be bonded onto the surface 711 of the insulation layer 710 of the interposer 700e through the connection pad 610. In some embodiments, at least one of the electronic element 801, the electronic element 802, and the electronic element 803 may also be replaced by the electronic device 10 of FIG. 1F.

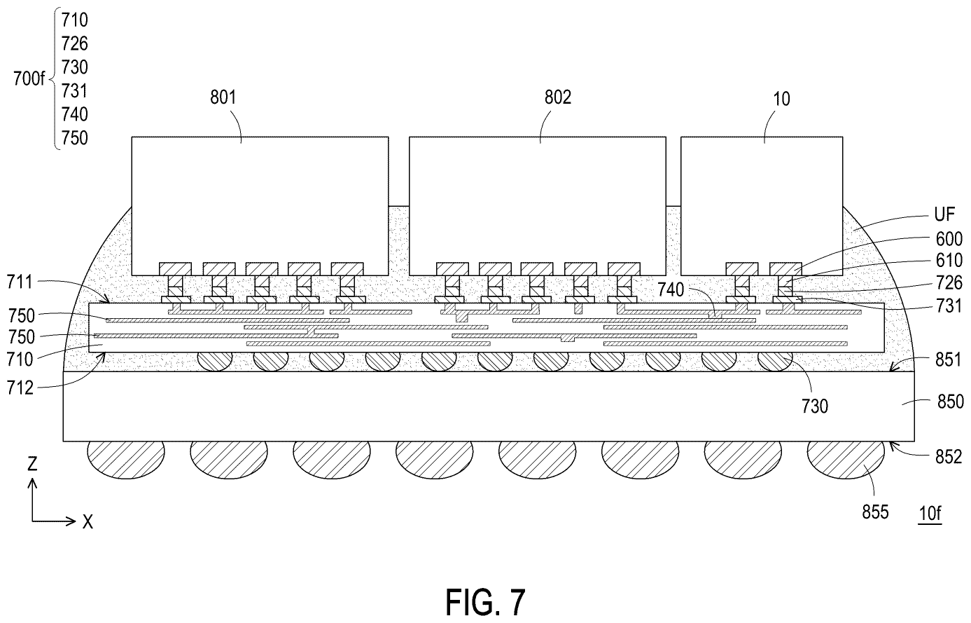

FIG. 7 is a schematic cross-sectional view of an electronic device according to a seventh embodiment of the disclosure. Please refer to FIG. 7 and FIG. 6 at the same time. An electronic device 10f of the embodiment is similar to the electronic device 10e in FIG. 6. The only difference between the two is that in the electronic device 10f of the embodiment, an interposer 700f is a redistribution layer or a redistribution structure.

Specifically, please refer to FIG. 7. The interposer 700f is disposed on the surface 851 of the circuit board 850. The interposer 700f may include the insulation layer 710, multiple conductive studs 726, the connection pads 730, multiple connection pads 731, the vias 740, and multiple metal layers 750. The insulation layer 710 has the surface 711 and the surface 712 opposite to each other. The connection pads 730 are respectively disposed on the surface 712 of the insulation layer 710, so that the interposer 700f may be bonded onto the surface 851 of the circuit board 850 through the connection pads 730. The connection pads 731 are respectively disposed on the surface 711 of the insulation layer 710. The conductive studs 726 are respectively disposed on the corresponding connection pad 731. The metal layers 750 are respectively disposed in the insulation layer 710. The vias 740 respectively penetrate a portion of the insulation layer 710. The vias 740 are filled with a conductive material, and the vias 740 may electrically connect different layers of the metal layers 750.

In some embodiments, the interposer 700f may be manufactured by adopting a manufacturing method similar to the manufacturing method (including the laser drilling process combined with the plasma etching process P in the second surface treatment process) of the circuit structure 400 in the electronic device 10f to reduce damage to the metal layer 750 or reduce the residue in the via 740, thereby reducing impedance (or contact resistance) between the metal layer 750 and other conductive materials, improving the electrical properties of the metal layer 750, or improving the adherence ability between the metal layer 750 and other conductive materials.

The electronic element 801, the electronic element 802, and the electronic device 10 of FIG. 1F include the connection pad 610 and the conductive stud 600 disposed on the connection pad 610, and the electronic element 801, the electronic element 802, and the electronic device 10 of FIG. 1F may be bonded onto the connection pad 731 of the interposer 700e through the connection pad 610 and the conductive stud 726. In some embodiments, at least one of the electronic element 801 and the electronic element 802 may also be replaced by the electronic device 10 of FIG. 1F.

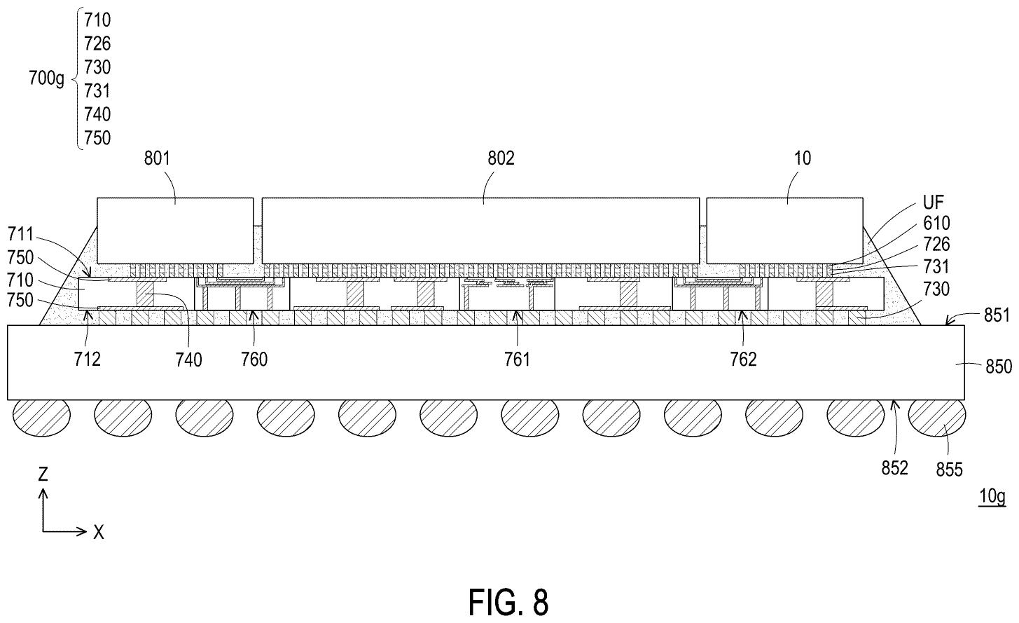

FIG. 8 is a schematic cross-sectional view of an electronic device according to an eighth embodiment of the disclosure. Please refer to FIG. 8 and FIG. 7 at the same time. An electronic device 10g of the embodiment is similar to the electronic device 10f in FIG. 7. The only difference between the two is that in the electronic device 10g of the embodiment, an interposer 700g also includes an electronic element 760, an electronic element 761, and an electronic element 762. For example, the electronic element may be a capacitor, a silicon-containing through-hole substrate, a chip, a circuit board, a combination thereof, or other suitable electronic elements. The electronic element 801 may be electrically connected to the electronic element 802 through the electronic element 760. Through the above design, electrical signal transmission path noise can be reduced or conditions such as chip offset can be improved, thereby improving the quality of the electronic device, but not limited thereto.

Specifically, please refer to FIG. 8. The electronic element 760, the electronic element 761, and the electronic element 762 are embedded in the insulation layer 710 of the interposer 700g. The electronic element 801, the electronic element 802, and the electronic device 10 of FIG. 1F may be electrically connected to the electronic element 760, the electronic element 761, and the electronic element 762 through the connection pad 610, the conductive stud 726, and the connection pad 731. The electronic element 760, the electronic element 761, and the electronic element 762 may be electrically connected to the circuit board 850 through the connection pad 730.

In some embodiments, at least one of the electronic element 760, the electronic element 761, and the electronic element 762 may also be replaced by the electronic device 10 of FIG. 1F.

In summary, in the electronic device of the embodiments of the disclosure, since the first surface treatment process uses the laser drilling process combined with the plasma etching process, damage to the pad can be reduced or the residue in the opening can be reduced (such as enabling the silicon content of the interface between the first metal layer and the pad to be less than 1%), thereby reducing impedance (or contact resistance) between the pad and other conductive materials (for example, the first metal layer), improving the electrical properties of the pad, or improving the adherence ability between the pad and other conductive materials (for example, the first metal layer). In addition, since the second surface treatment process uses the laser drilling process combined with the plasma etching process, damage to the first metal layer in the circuit structure can be reduced or the residue in the via can be reduced (such as enabling the silicon content and/or the carbon content of the interface between the second metal layer and the first metal layers to be less than 1%), thereby reducing impedance (or contact resistance) between the first metal layer and other conductive materials (for example, the second metal layer), improving the electrical properties of the first metal layer, or improving the adherence ability between the first metal layer and other conductive materials (for example, the second metal layer).

Finally, it should be noted that the above embodiments are only used to illustrate, but not to limit, the technical solutions of the disclosure. Although the disclosure has been described in detail with reference to the above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. An electronic device, comprising:
a chip, comprising a base layer and at least one pad, wherein the at least one pad is disposed on a first side of the base layer;
a protective layer, disposed on the first side and having at least one opening, wherein the at least one opening exposes a portion of the at least one pad;
an encapsulation layer, surrounding the chip and the protective layer; and
a circuit structure, disposed on the encapsulation layer and electrically connected to the chip;
wherein the at least one pad has a concave surface, and a portion of the circuit structure contacts the concave surface.

2. The electronic device according to claim 1, wherein a depth of the concave surface of the at least one pad is 30 nm to 70 nm.

3. The electronic device according to claim 1, wherein a ratio of a depth of the concave surface of the at least one pad to a height of the at least one pad is 1% to 15%.

4. The electronic device according to claim 3, wherein the ratio is 3% to 10%.

5. The electronic device according to claim 1, wherein the at least one opening of the protective layer overlaps with the concave surface of the at least one pad and the portion of the circuit structure contacts the concave surface through the least one opening of the protective layer.

6. The electronic device according to claim 1, wherein the protective layer contacts the first side of the base layer.

7. The electronic device according to claim 1, wherein the circuit structure comprises:
a first metal layer, having a recession;
a first insulation layer, disposed on the first metal layer and comprising a via;
a second metal layer, disposed on the first insulation layer and electrically connected to the first metal layer through the via of the first insulation layer; and
a second insulation layer, disposed on the second metal layer,
wherein the via overlaps with the recession of the first metal layer.

8. The electronic device according to claim 7, wherein a depth of the recession is 0.1 μm to 5 μm.

9. The electronic device according to claim 7, wherein the first metal layer contacts the concave surface of the at least one pad.

10. The electronic device according to claim 7, wherein the second metal layer contacts the recession of the first metal layer.

11. The electronic device according to claim 1, further comprising:
an insulation layer, disposed between the chip and the protective layer, wherein the insulation layer has an opening, and the opening exposes a portion of the at least one pad,
wherein a portion of the protective layer is disposed in the opening of the insulation layer.

12. The electronic device according to claim 1, further comprising:
an insulation layer, disposed between the chip and the protective layer, wherein the insulation layer has an opening, and the opening exposes a portion of the at least one pad,
wherein a width of the at least one opening of the protective layer is greater than a width of the opening of the insulation layer.

13. The electronic device according to claim 1, wherein the chip also has a lateral surface connected to the first side, and the protective layer has a lateral surface,
wherein the lateral surface of the protective layer is an inclined surface, there is an arc surface connecting the lateral surface and the first side of the chip, and the encapsulation layer contacts the arc surface.

14. A manufacturing method of an electronic device, comprising:
providing a chip, wherein the chip comprises a base layer and at least one pad, and the at least one pad is disposed on a first side of the base layer;
forming a protective layer on the first side, wherein the protective layer has at least one opening, and the at least one opening exposes a portion of the at least one pad;
forming an encapsulation layer to surround the chip and the protective layer; and
forming a circuit structure on the encapsulation layer to electrically connect the chip;
wherein the at least one pad has a concave surface, and a portion of the circuit structure contacts the concave surface.

15. The manufacturing method according to claim 14, wherein forming the at least one opening and the concave surface comprises:
performing a laser drilling process on the protective layer to form a first opening exposing a portion of the at least one pad; and
performing a plasma etching process on the first opening of the protective layer to form the at least one opening and the concave surface.

16. The manufacturing method according to claim 15, wherein a width of the at least one opening is greater than a width of the first opening.

17. The manufacturing method according to claim 14, wherein the circuit structure comprises:
a first metal layer, having a recession;
a first insulation layer, disposed on the first metal layer and comprising a via;
a second metal layer, disposed on the first insulation layer and electrically connected to the first metal layer through the via of the first insulation layer; and
a second insulation layer, disposed on the second metal layer,
wherein the via overlaps with the recession of the first metal layer.

18. The manufacturing method according to claim 17, wherein forming the via and the recession comprises:
performing a laser drilling process on the first insulation layer to form a first via exposing a portion of the first metal layer, and
performing a plasma etching process on the first via of the first insulation layer to form the via and the recession.

19. The manufacturing method according to claim 10, wherein the first metal layer contacts the concave surface of the at least one pad.

20. The manufacturing method according to claim 10, wherein the second metal layer contacts the recession of the first metal layer.
